(19) United States
(12) Patent Application Publication
(10) Pub. No.: US 2026/0324001 A1
(43) Pub. Date: Oct. 15, 2026

(54) DISPLAY PANEL AND DISPLAY DEVICE

(71) Applicants: Beijing BOE Technology Development Co., Ltd., Beijing (CN); BOE TECHNOLOGY GROUP CO., LTD., Beijing (CN)

(72) Inventors: Hao LIU, Beijing (CN); Ran LI, Beijing (CN); Huijuan ZHANG, Beijing (CN); Libin LIU, Beijing (CN)

(73) Assignees: Beijing BOE Technology Development Co., Ltd., Beijing (CN); BOE TECHNOLOGY GROUP CO., LTD., Beijing (CN)

(21) Appl. No.: 19/100,585

(22) PCT Filed: Nov. 30, 2023
(86) PCT No.: PCT/CN2023/135269

§ 371 Date: Feb. 3, 2025

(51) Int. Cl. H10D 30/67; H10D 86/40; H10D 86/60

(52) U.S. Cl. CPC H10D 30/6738; H10D 30/6732; H10D 30/6757; H10D 86/441; H10D 86/481; H10D 86/60

(57) ABSTRACT

A display substrate includes: a base substrate; a plurality of first barrier structures arranged in an array on a side of the base substrate, each of the first barrier structures enclosing a first region; and a first electrode layer comprising a plurality of first electrodes, the plurality of first electrodes being arranged corresponding to the plurality of first barrier structures, and each of the first electrodes being within the first region enclosed by the corresponding first barrier structure, wherein each of the first barrier structures has a first height in a thickness direction of the base substrate, each of the first electrodes has a second height in the thickness direction of the base substrate, the first height is greater than the second height, and a separation groove is provided on a side surface of each of the first barrier structures away from the base substrate.

### CROSS-REFERENCE TO RELATED APPLICATION

This disclosure is the U.S. national phase application of PCT Application No. PCT/CN2023/135269, filed on Nov. 30, 2023 and entitled “Display Panel and Display Device”, the entire content of which is incorporated herein by reference in its entirety.

### TECHNICAL FIELD

This disclosure relates to the field of display technology and, more particularly, to a display panel and a display device.

### BACKGROUND

A pixel drive circuit includes a drive transistor, and the pixel drive circuit outputs a drive current based on a gate-source voltage difference of the drive transistor. In the related art, the drive transistor generally employs a low-temperature polycrystalline silicon transistor. However, on the one hand, the low-temperature polycrystalline silicon transistor exhibits a significant warpage effect at a relatively small channel length, thereby leading to poor display uniformity of a display panel; on the other hand, the low-temperature polycrystalline silicon transistor has a relatively high saturation voltage, thereby increasing power consumption of the display panel; furthermore, the low-temperature polycrystalline silicon transistor has poor uniformity in output characteristics during low grayscale display.

It should be noted that information disclosed in the Background is only used to acquire a better understanding of the background of this disclosure and therefore may include information that does not constitute the related art already known to those skilled in the art.

### SUMMARY

According to one aspect of this disclosure, there is provided a display panel, including a pixel drive circuit. The pixel drive circuit includes a drive transistor, and the drive transistor outputs a drive current based on a gate-source voltage difference thereof. The display panel further includes:
a base substrate;
a first active portion including a first active sub-portion and a second active sub-portion connected to each other, the first active sub-portion being configured to form a channel region of the drive transistor, and the second active sub-portion being of a semiconductor structure;
a source portion having a conductor structure, the source portion and the second active sub-portion forming a Schottky contact, and the source portion being configured to form a source of the drive transistor; and
a gate portion, an orthographic projection of the gate portion on the base substrate covering an orthographic projection of the first active sub-portion on the base substrate, and the gate portion being configured to form a gate of the drive transistor,
wherein in a stacking direction of the base substrate and the first active portion, at least a part of the source portion and at least a part of the gate portion are respectively located on two sides of the second active sub-portion, and orthographic projections of the source portion and the gate portion located on the two sides of the second active sub-portion on the base substrate at least partially overlap.

In an exemplary embodiment of this disclosure, a conduction band minimum of the second active sub-portion is less than a work function of a contact portion of the source portion with the second active sub-portion.

In an exemplary embodiment of this disclosure, a difference between the work function of the contact portion of the source portion with the second active sub-portion and the conduction band minimum of the second active sub-portion is greater than or equal to 0.3 eV.

In an exemplary embodiment of this disclosure, orthographic projections of the source portion and the gate portion located on the two sides of the second active sub-portion on the base substrate and an orthographic projection of the second active sub-portion on the base substrate have a common overlapping region.

In an exemplary embodiment of this disclosure, the source portion includes a first source portion and a second source portion;
the first source portion is connected to the second active sub-portion through a via hole, and the first source portion conformally covers at least a part of a sidewall and at least a part of a bottom wall of the via hole;
the second source portion is located on a side of the first source portion away from the second active sub-portion, and the second source portion at least partially fills the via hole.

In an exemplary embodiment of this disclosure, the first source portion includes one or more of silver oxide, platinum, titanium oxide, and molybdenum oxide.

In an exemplary embodiment of this disclosure, the source portion is located on a side of the first active portion away from the base substrate, and the gate portion is located between the first active portion and the base substrate.

In an exemplary embodiment of this disclosure, the gate portion is located on a side of the first active portion away from the base substrate;
the source portion includes a third source portion and a fourth source portion, the third source portion forms a Schottky contact with the second active sub-portion, the third source portion is at least partially located between the second active sub-portion and the base substrate, and the fourth source portion is connected to the third source portion through a via hole;
an orthographic projection of the third source portion on the base substrate at least partially overlap with the orthographic projection of the gate portion on the base substrate.

In an exemplary embodiment of this disclosure, the drive transistor is an N-type transistor, a source of the drive transistor is an output terminal of the drive current, and the pixel drive circuit further includes a capacitor, a first electrode of the capacitor being connected to the gate of the drive transistor, and a second electrode of the capacitor being connected to the source of the drive transistor;
at least a part of the gate portion is reused as the first electrode of the capacitor, and at least a part of the source portion is reused as the second electrode of the capacitor.

In an exemplary embodiment of this disclosure, the first active portion further includes a third active sub-portion, and the first active sub-portion is connected between the second active sub-portion and the third active sub-portion;
the display panel further includes:
a drain portion having a conductor structure, the drain portion forming a Schottky contact with the third active sub-portion, and the drain portion being configured to form a drain of the drive transistor.

In an exemplary embodiment of this disclosure, a width-to-length ratio of the channel region of the drive transistor is 2/2 to 2/10.

In an exemplary embodiment of this disclosure, the display panel further includes:
a gate layer on a side of the base substrate, the gate layer including the gate portion;
an active layer on a side of the gate layer away from the base substrate, the active layer including the first active portion;
a Schottky contact layer including a first source portion, the first source portion and the second active sub-portion forming a Schottky contact; and
a first source-drain layer on a side of the Schottky contact layer away from the base substrate, the first source-drain layer including a second source portion, and the second source portion being electrically connected to the first source portion,
wherein the first source portion and the second source portion constitute the source portion.

In an exemplary embodiment of this disclosure, the display panel further includes:
a dielectric layer between the active layer and the Schottky contact layer, the dielectric layer being provided with a via hole, and the via hole exposing at least a part of the second active sub-portion out of the dielectric layer,
wherein the first source portion conformally covers at least a part of a sidewall and at least a part of a bottom wall of the via hole, and the second source portion at least partially fills the via hole.

In an exemplary embodiment of this disclosure, wherein the first active portion further includes a third active sub-portion, and the first active sub-portion is connected between the second active sub-portion and the third active sub-portion;
the Schottky contact layer includes a first drain portion, and the first drain portion and the third active sub-portion form a Schottky contact;
the first source-drain layer further includes a second drain portion, the second drain portion is electrically connected to the first drain portion, and the first drain portion and the second drain portion constitute a drain of the drive transistor.

In an exemplary embodiment of this disclosure, a length direction of the channel region of the drive transistor is a first direction;
the gate portion includes a first gate portion; the second source portion includes a first conductive portion; an orthographic projection of the first gate portion on the base substrate is located on a side, in a second direction, of an orthographic projection of the first active sub-portion on the base substrate; and an orthographic projection of the second source portion on the base substrate is located on a side, in the second direction, of the orthographic projection of the first active sub-portion on the base substrate;
the orthographic projection of the first gate portion on the base substrate at least partially overlaps with an orthographic projection of the first conductive portion on the base substrate, and the first direction intersects with the second direction.

In an exemplary embodiment of this disclosure, the pixel drive circuit further includes a fourth transistor, and the fourth transistor has a first pole connected to an initial signal line, a second pole connected to the source of the drive transistor, and a gate connected to a reset signal line;
the gate layer further includes the reset signal line, and an orthographic projection of the reset signal line on the base substrate extends in the first direction;
in the second direction, the orthographic projection of the first gate portion on the base substrate and the orthographic projection of the second source portion on the base substrate are located between the orthographic projection of the reset signal line on the base substrate and the orthographic projection of the first active sub-portion on the base substrate.

In an exemplary embodiment of this disclosure, the pixel drive circuit further includes a switching transistor;
the gate layer further includes a gate line, an orthographic projection of the gate line on the base substrate extends in a first direction, and a part of the gate line is configured to form a gate of the switching transistor;
wherein the gate line includes gate sub-lines spaced apart and extending in the first direction, the first source-drain layer further includes a connection line, an orthographic projection of the connection line on the base substrate extends in the first direction, and the connection line connects a plurality of gate sub-lines in a same gate line through via holes;
a sheet resistance of the gate layer is greater than a sheet resistance of the first source-drain layer.

In an exemplary embodiment of this disclosure, the pixel drive circuit further includes:
a second transistor having a first pole connected to a data line, a second pole connected to the gate of the drive transistor, and a gate connected to a second gate line;
a third transistor having a first pole connected to a reference voltage line, a second pole connected to the gate of the drive transistor, and a gate connected to a first gate line;
a fourth transistor having a first pole connected to an initial signal line, a second pole connected to the source of the drive transistor, and a gate connected to a reset signal line; and
a fifth transistor having a first pole connected to a power line, a second pole connected to a drain of the drive transistor, and a gate connected to an enable signal line,
wherein the first gate line, the second gate line, the reset signal line, and the enable signal line are located in the gate layer, a part of the first gate line is configured to form a gate of the third transistor; a part of the second gate line is configured to form a gate of the second transistor; a part of the reset signal line is configured to form a gate of the fourth transistor, and a part of the enable signal line is configured to form a gate of the fifth transistor;
orthographic projections of the first gate line, the second gate line, the reset signal line, and the enable signal line on the base substrate extend in a first direction;
in a same pixel drive circuit, an orthographic projection of the enable signal line on the base substrate, an orthographic projection of the reset signal line on the base substrate, an orthographic projection of the gate portion on the base substrate, an orthographic projection of the second gate line on the base substrate, and an orthographic projection of the first gate line on the base substrate are sequentially distributed in a second direction, and the first direction intersects with the second direction.

In an exemplary embodiment of this disclosure, according to one aspect of this disclosure, there is provided a display device, including the display panel described above.

It should be understood that the foregoing general description and the following detailed description are exemplary and explanatory only and are not restrictive of this disclosure.

### BRIEF DESCRIPTION OF THE DRAWINGS

The accompanying drawings, which are incorporated into and constitute a part of this specification, illustrate embodiments consistent with this disclosure, and serve to explain the principles of this disclosure together with the description. It is apparent that the drawings in the following description are merely some embodiments of this disclosure. For those skilled in the art, other drawings may be derived from these figures without creative effort.

FIG. 1 is a schematic structural view of a drive transistor in an exemplary embodiment of a display panel according to this disclosure;

FIG. 2 is a schematic view showing a working principle of a drive transistor in a display panel according to this disclosure;

FIG. 3 is a schematic structural view of a drive transistor in another exemplary embodiment of a display panel according to this disclosure;

FIG. 4 is a schematic structural view of a drive transistor in another exemplary embodiment of a display panel according to this disclosure;

FIG. 5 is a schematic structural view of a pixel drive circuit in an exemplary embodiment of a display panel according to this disclosure;

FIG. 6 is a timing diagram of nodes in a driving method for the pixel drive circuit shown in FIG. 5;

FIG. 7 is a structural layout of an exemplary embodiment of a display panel according to this disclosure;

FIG. 8 is a structural layout of a gate layer in the display panel shown in FIG. 7;

FIG. 9 is a structural layout of an active layer in the display panel shown in FIG. 7;

FIG. 10 is a structural layout of a Schottky contact layer in the display panel shown in FIG. 7;

FIG. 11 is a structural layout of a first source-drain layer in the display panel shown in FIG. 7;

FIG. 12 is a structural layout of a second source-drain layer in the display panel shown in FIG. 7;

FIG. 13 is a structural layout of a gate layer and an active layer in the display panel shown in FIG. 7;

FIG. 14 is a structural layout of a gate layer, an active layer, and a Schottky contact layer in the display panel shown in FIG. 7;

FIG. 15 is a structural layout of a gate layer, an active layer, a Schottky contact layer, and a first source-drain layer in the display panel shown in FIG. 7;

FIG. 16 is a structural layout of a gate layer, an active layer, a Schottky contact layer, a first source-drain layer, and a second source-drain layer in the display panel shown in FIG. 7;

FIG. 17 is a partial sectional view of the display panel shown in FIG. 7 taken along a dashed line AA.

### DETAILED DESCRIPTION

Exemplary embodiments will be now described more fully with reference to the accompanying drawings. However, the exemplary embodiments can be embodied in a variety of forms and should not be construed as limiting the embodiments set forth herein. Instead, these embodiments are provided so that this disclosure will be thorough and complete, and the concepts of the exemplary embodiments will be fully given to those skilled in the art. Same reference numbers denote the same or similar structures in the figures, and thus the detailed description thereof will be omitted.

Words such as “one,” “an/a,” and “said” are used herein to indicate the presence of one or more elements/component parts/and others. Terms “including” and “having” have an inclusive meaning which means that there may be additional elements/component parts/and others in addition to the listed elements/component parts/and others.

In the related art, a drive transistor operates in a saturation region, and a source-drain voltage difference of the drive transistor is equal to a sum of a saturation voltage and a compensation voltage of the drive transistor. The saturation voltage of the drive transistor is a minimum source-drain voltage required for the drive transistor to enter the saturation region, and a compensation voltage is used to compensate for voltage drop of signal lines in the display panel. In the related art, the saturation voltage of the drive transistor is relatively high, and accordingly, the compensation voltage is also relatively high. The drive transistor operates under a higher source-drain voltage difference, thereby increasing power consumption of the display panel. Additionally, in the related art, a warpage effect of the drive transistor is relatively significant, which may affect display uniformity of the display panel.

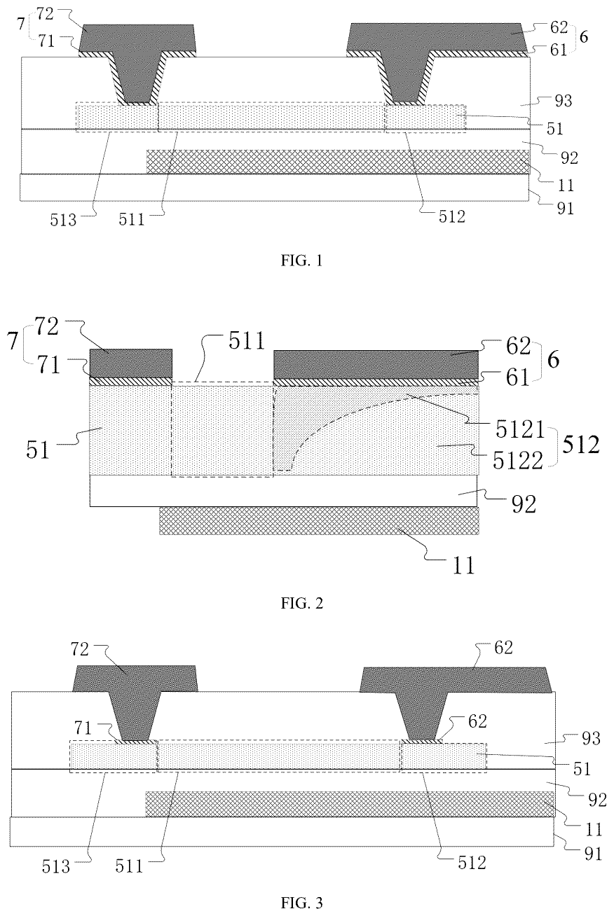

An exemplary embodiment of this disclosure first provides a display panel. The display panel includes a pixel drive circuit. The pixel drive circuit includes a drive transistor that outputs a drive current based on its gate-source voltage difference. As shown in FIG. 1, it is a schematic structural view of the drive transistor in an exemplary embodiment of the display panel according to this disclosure. The display panel further includes: a base substrate 91, a first active portion 51, a source portion 6, and a gate portion 11. The first active portion 51 includes a first active sub-portion 511 and a second active sub-portion 512 connected to each other. The first active sub-portion 511 is configured to form a channel region of the drive transistor, and the second active sub-portion 512 is a semiconductor structure. The source portion 6 is a conductor structure, and the source portion 6 and the second active sub-portion 512 form a Schottky contact. The source portion 6 is configured to form a source of the drive transistor. An orthographic projection of the gate portion 11 on the base substrate 91 covers an orthographic projection of the first active sub-portion 511 on the base substrate. The gate portion 11 is configured to form a gate of the drive transistor T1. In a stacking direction of the base substrate 91 and the first active portion 51, at least part of the source portion 6 and at least part of the gate portion 11 are located on both sides of the second active sub-portion 512, and orthographic projections of the source portion 6 and the gate portion 11 on the base substrate at least partially overlap.

In this exemplary embodiment, a Schottky contact is formed between the source portion 6 and the second active sub-portion 512 of the drive transistor. A potential barrier is formed between the source portion 6 and the second active sub-portion 512. The gate-source voltage difference of the drive transistor may adjust the potential barrier between the source portion 6 and the second active sub-portion 512, thereby regulating output current of the drive transistor. As shown in FIG. 2, it is a working principle view of the drive transistor in the display panel according to this disclosure, in this exemplary embodiment, an electric field is formed in the second active sub-portion 512 by using the source portion 6 and the gate portion 11 on both sides of the second active sub-portion 512. This electric field may form a depletion layer 5121 and an accumulation layer 5122 in the second active sub-portion 512. The depletion layer 5121 may form an auxiliary current path between the source and the drain of the drive transistor, thereby regulating the output characteristics of the drive transistor. In this exemplary embodiment, the drive transistor is configured as a source-gated transistor (SGT) through the above structure. The SGT has a small saturation voltage, a minimal warpage effect, and a wide saturation voltage range. Additionally, the SGT exhibits stable output characteristics while a low current is output, thereby reducing the power consumption of the display panel and improving the display uniformity of the display panel.

In this exemplary embodiment, a conduction band minimum of the second active sub-portion 512 is less than a work function of a contact portion between the source portion 6 and the second active sub-portion 512. The difference between the work function of the contact portion between the source portion 6 and the second active sub-portion 512 and the conduction band minimum of the second active sub-portion 512 is greater than or equal to 0.3 eV. For example, the difference between the work function of the contact portion between the source portion 6 and the second active sub-portion 512 and the conduction band minimum of the second active sub-portion 512 may be 0.3 eV, 0.4 eV, 0.5 eV, 0.6 eV, 0.7 eV, 0.8 eV, 0.9 eV, 1 eV, 2 eV, 3 eV, 4 eV, 5 eV, etc.

In this exemplary embodiment, as shown in FIG. 1, orthographic projections of the source portion 6 and the gate portion 11 on both sides of the second active sub-portion 512 on the base substrate 91 and the orthographic projection of the second active sub-portion 512 on the base substrate have a common overlapping region, that is, the three orthographic projections share the common overlapping region. This arrangement allows the second active sub-portion 512 to be located between parallel-plate capacitor structures formed by the source portion 6 and the gate portion 11, thereby facilitating the formation of the depletion layer and the accumulation layer on the second active sub-portion 512.

It should be understood that in other exemplary embodiments, the orthographic projection of the second active sub-portion 512 on the base substrate may also be located outside the overlapping region of the orthographic projections of the source portion 6 and the gate portion 11 on the base substrate 91. That is, the second active sub-portion 512 is located outside the parallel-plate capacitor structure formed by the source portion 6 and the gate portion 11. Additionally, in other exemplary embodiments, the drive transistor may also be source-gated transistors with other structures.

In this exemplary embodiment, as shown in FIG. 1, the source portion 6 may include a first source portion 61 and a second source portion 62. The first source portion 61 is connected to the second active sub-portion 512 through a via hole, and the first source portion 61 conformally covers at least part of the sidewall and at least part of the bottom wall of the via hole. The second source portion 62 is located on a side of the first source portion 61 away from the second active sub-portion 512, and the second source portion 62 at least partially fills the via hole. The bottom wall of the via hole is formed by the second active sub-portion 512. The first source portion 61 is generally made of precious metal materials, such as silver oxide, platinum, titanium oxide, molybdenum oxide, or a combination thereof. In this exemplary embodiment, the first source portion 61 conformally covers the sidewall and the bottom wall of the via hole, thereby reducing a volume of the first source portion 61. The second source portion 62 is in Ohmic contact with the first source portion 61 and may be made of low-cost metals, such as molybdenum, aluminum, copper, titanium, niobium, or alloys thereof, or molybdenum/titanium alloy or laminated structures, or conductive layers such as titanium/aluminum/titanium laminates.

In this exemplary embodiment, the first active portion 51 may be made of indium gallium zinc oxide (IGZO), indium tin oxide (ITO), indium gallium tin oxide (IGTO), or the like.

In this exemplary embodiment, as shown in FIG. 1, the source portion 6 is located on a side of the first active portion 51 away from the base substrate 91, and the gate portion 11 is located between the first active portion 51 and the base substrate 91. That is, the drive transistor has a bottom-gate structure.

In this exemplary embodiment, as shown in FIG. 1, the display panel may further include a first insulating layer 92 and a dielectric layer 93. The first insulating layer 92 is located between the gate portion 11 and the first active portion 51, and the dielectric layer 93 is located between the first active portion 51 and the source portion 6.

In this exemplary embodiment, as shown in FIG. 1, the first active portion 51 may further include a third active sub-portion 513. The first active sub-portion 511 is connected between the second active sub-portion 512 and the third active sub-portion 513. The display panel further includes a drain portion 7, which is a conductor structure. The drain portion 7 and the third active sub-portion 513 form a Schottky contact, and the drain portion 7 is configured to form a drain of the drive transistor. As shown in FIG. 1, the drain portion 7 may include a first drain portion 71 and a second drain portion 72. The first drain portion 71 is connected to the third active sub-portion 513 through a via hole, and the first drain portion 71 conformally covers at least part of the sidewall and at least part of the bottom wall of the via hole. The second drain portion 72 is located on a side of the first drain portion 71 away from the third active sub-portion 513, and the second drain portion 72 at least partially fills the via hole. The first drain portion 71 may include silver oxide, platinum, titanium oxide, molybdenum oxide, or a combination thereof. The second drain portion 72 is in Ohmic contact with the first drain portion 71 and may be made of molybdenum, aluminum, copper, titanium, niobium, or alloys thereof, or molybdenum/titanium alloy or laminated structures, or conductive layers such as titanium/aluminum/titanium laminates.

In this exemplary embodiment, a manufacturing method of the display panel may include: forming a gate portion 11 on a base substrate 91 through a patterning process; forming a first insulating layer 92 on the gate portion 11; forming a first active portion 51 on the first insulating layer 92 through the patterning process; forming the dielectric layer 93 on the first active portion 51; forming at least two via holes in the dielectric layer 93 to expose at least part of the second active sub-portion 512 and at least part of the third active sub-portion 513; depositing a first source portion 61 and a first drain portion 71 in the via holes through a sputtering process; and finally, forming a second source portion 62 and a second drain portion 72 on the first source portion 61 and the first drain portion 71, respectively.

It should be understood that in other exemplary embodiments, the first source portion 61 may have other configurations. For example, as shown in FIG. 3, which is a schematic structural view of a drive transistor according to another exemplary embodiment of the display panel according to this disclosure, the first source portion 61 and the first drain portion 71 may be located between the dielectric layer 93 and the first active portion 51.

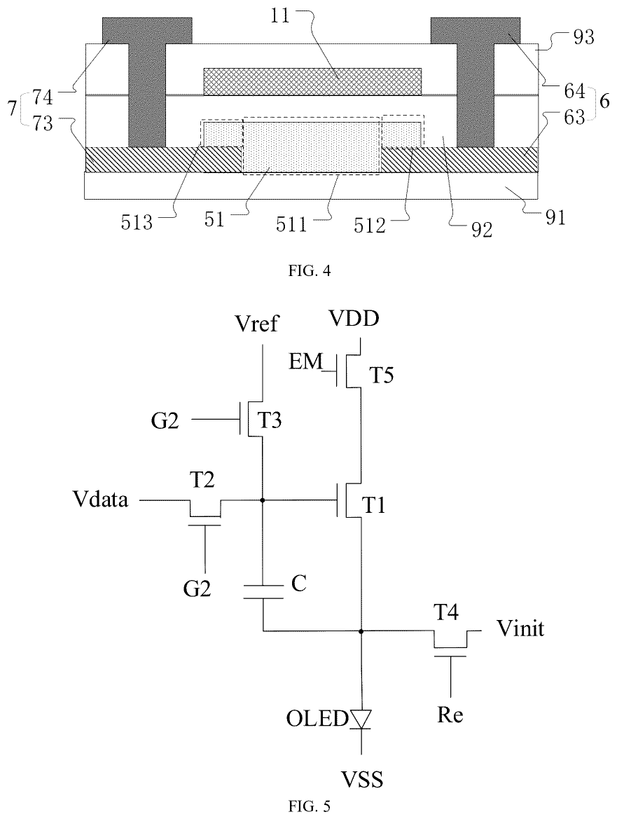

Furthermore, in other exemplary embodiments, the drive transistor may also have a top-gate structure. As shown in FIG. 4, it is a schematic structural view of a drive transistor in another exemplary embodiment of the display panel according to this disclosure. The gate portion 11 may be located on the side of the first active portion 51 away from the base substrate 91. The source portion 6 may include a third source portion 63 and a fourth source portion 64. The third source portion 63 forms a Schottky contact with the second active sub-portion 512. The third source portion 63 is at least partially located between the second active sub-portion 512 and the base substrate 91. The fourth source portion 64 is connected to the third source portion 63 through a via hole. An orthographic projection of the third source portion 63 on the base substrate and the orthographic projection of the gate portion 11 on the base substrate at least partially overlap.

As shown in FIG. 4, the drain portion 7 may also include a third drain portion 73 and a fourth drain portion 74. The third drain portion 73 forms a Schottky contact with the third active sub-portion 513. The third drain portion 73 is at least partially located between the third active sub-portion 513 and the base substrate 91. The fourth drain portion 74 is connected to the third drain portion 73 through a via hole.

In this exemplary embodiment, the drive transistor may be an N-type transistor. The source of the drive transistor is an output terminal of the drive current. The pixel drive circuit further includes a capacitor. The first electrode of the capacitor is connected to the gate of the drive transistor, and the second electrode of the capacitor is connected to the source of the drive transistor. The capacitor is configured to maintain the gate-source voltage difference of the drive transistor when the drive transistor outputs current to its source, thereby maintaining a constant output current. In the source-gated transistor provided in this exemplary embodiment, at least part of the structure of the gate portion 11 may be reused as the first electrode of the capacitor, and at least part of the structure of the source portion 6 may be reused as the second electrode of the capacitor. This display panel may save space for the capacitor, thereby improving an integration level of the display panel.

In this exemplary embodiment, the source-gated transistor has a small saturation voltage, minimal warpage effect, and a wide saturation voltage range. The source-gated transistor may be designed with a small channel length while ensuring the required output characteristics. In this exemplary embodiment, a width-to-length ratio of the channel region of the drive transistor may be 2/2-2/10. For example, the width-to-length ratio of the channel region of the drive transistor may be 2/2, 2/3, 2/4, 2/5, 2/6, 2/7, 2/8, 2/9, or 2/10 etc.

As shown in FIG. 5, it is a schematic structural view of a pixel drive circuit in an exemplary embodiment of the display panel according to this disclosure. The pixel drive circuit includes: a drive transistor T1, a second transistor T2, a third transistor T3, a fourth transistor T4, a fifth transistor T5, and a capacitor C. The second transistor T2 has a first pole connected to a data line (Data), a second pole connected to the gate of the drive transistor T1, and a gate connected to the second gate line G2. The third transistor T3 has a first pole connected to a reference voltage line Vref, a second pole connected to the gate of the drive transistor T1, and a gate connected to the first gate line G1. The fourth transistor T4 has a first pole connected to an initial signal line Vinit, a second pole connected to the source of the drive transistor T1, and a gate connected to a reset signal line Re. The fifth transistor T5 has a first pole connected to a power line VDD, a second pole connected to the drain of the drive transistor T1, and a gate connected to an enable signal line EM. Here, the drive transistor T1, the second transistor T2, the third transistor T3, the fourth transistor T4, and the fifth transistor T5 are all N-type transistors. The capacitor C has a first electrode connected to the gate of the drive transistor, and a second electrode connected to the source of the drive transistor. The pixel drive circuit is configured to drive the light-emitting unit OLED. The light-emitting unit OLED has a first electrode connected to the source of the drive transistor, and a second electrode connected to a common electrode VSS.

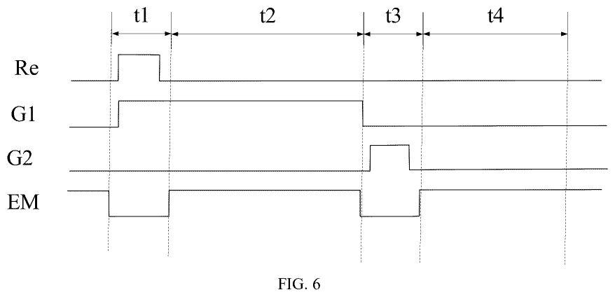

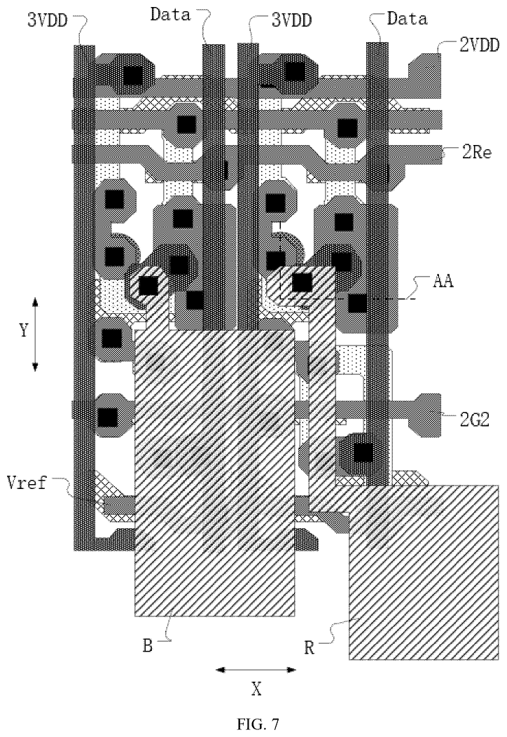

As shown in FIG. 6, it is a timing diagram of nodes in a driving method of the pixel drive circuit shown in FIG. 5. Here, Re is a timing diagram of the reset signal line, G1 is a timing diagram of the first gate line, G2 is a timing diagram of the second gate line, and EM is a timing diagram of the enable signal line.

The driving method of the pixel drive circuit includes: an initialization phase t1, a threshold compensation phase t2, a data writing phase t3, and a light-emitting phase t4. In the initialization phase t1: the reset signal line Rel and the first gate line G1 output high-level signals, the third transistor T3 and the fourth transistor T4 are turned on, the initial signal line Vinit inputs an initial signal to the source of the drive transistor T1, and the reference voltage line Vref inputs a reference voltage to the gate of the drive transistor T1. In the threshold compensation phase t2: the first gate line G1 and the enable signal line EM output high-level signals, the third transistor T3 remains turned on, the reference voltage line Vref continuously inputs the reference voltage Vf to the gate of the drive transistor T1, and the source voltage of the drive transistor T1 becomes Vf-Vth, where Vth is a threshold voltage of the drive transistor. In the data writing phase t3: the second gate line G2 outputs high-level signals, the second transistor T2 is turned on, and the data line Data writes a data signal Vda to the gate of the drive transistor. In the light-emitting phase t4: the enable signal line EM outputs high-level signals, the fifth transistor T5 is turned on, and the drive transistor T1 outputs a drive current. The drive current I=(μWCox/2L)(Vgs−Vth)2=(μWCox/2L)(Vda−(Vf−Vth)−Vth)2, where μ is a carrier mobility, Cox is a gate capacitance per unit area, W is a width of the channel of the drive transistor, L is a length of the channel of the drive transistor, Vgs is a gate-source voltage difference of the drive transistor, and Vth is a threshold voltage of the drive transistor. The pixel drive circuit may avoid the influence of the threshold voltage of the drive transistor on its output current.

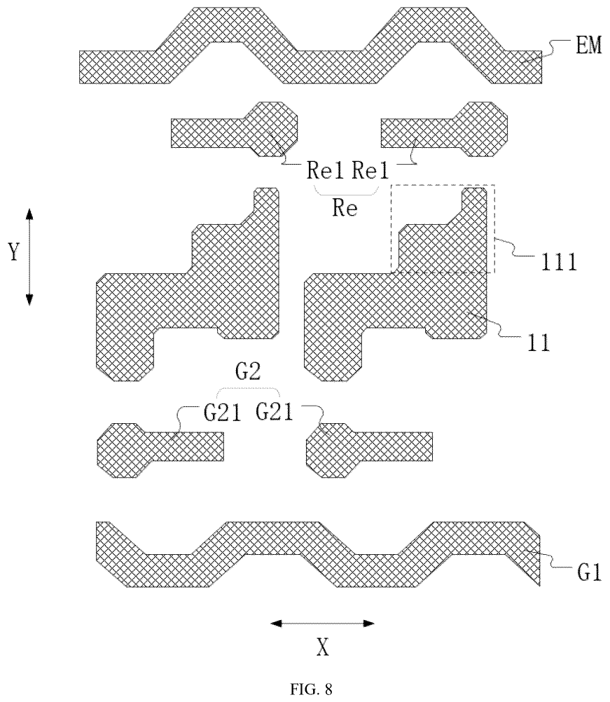

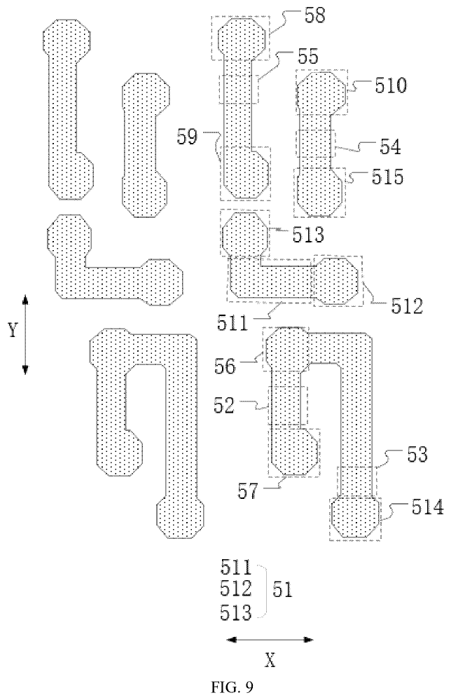

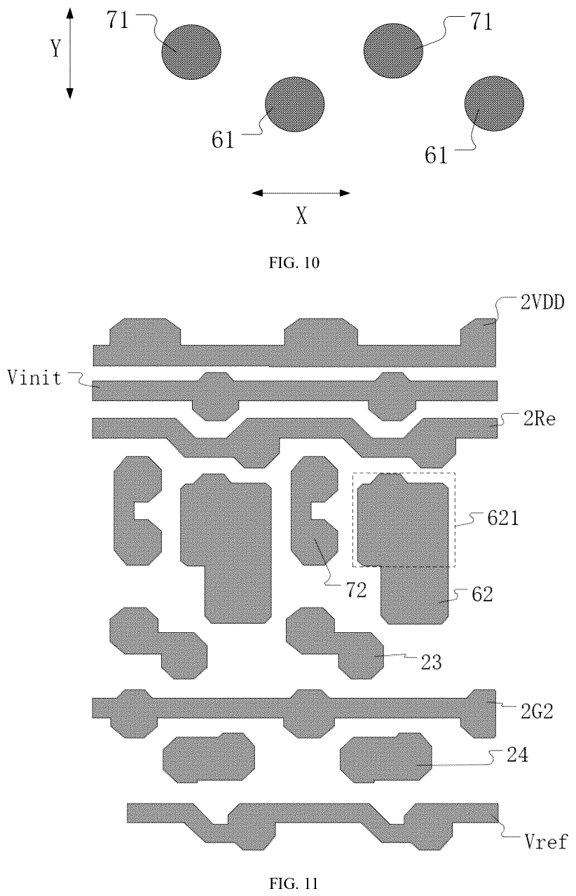

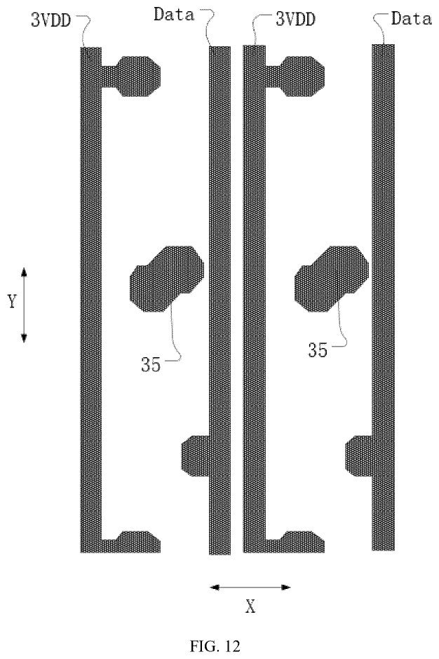

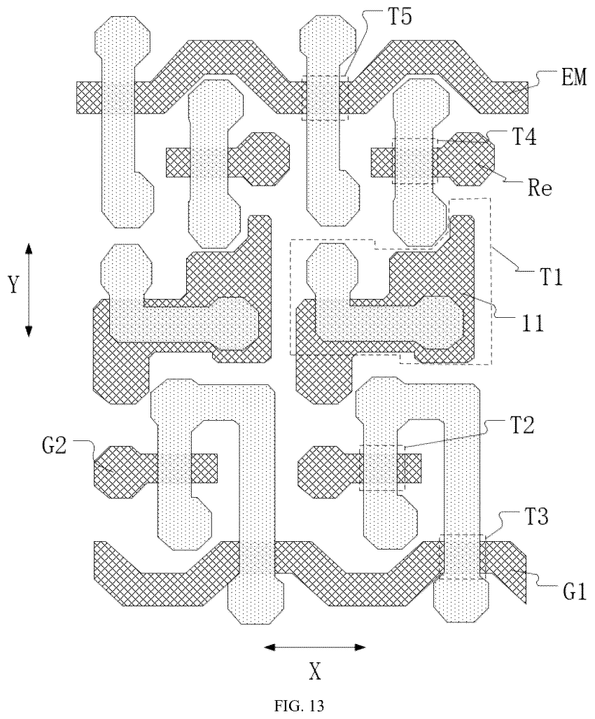

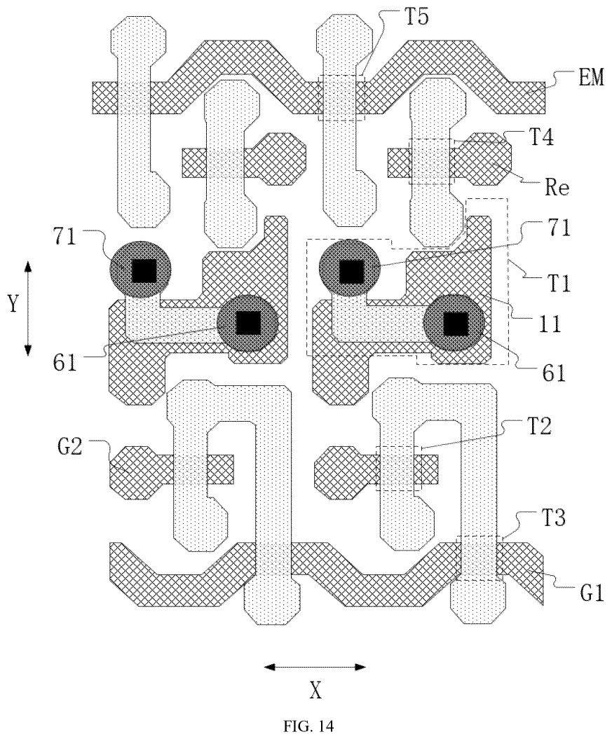

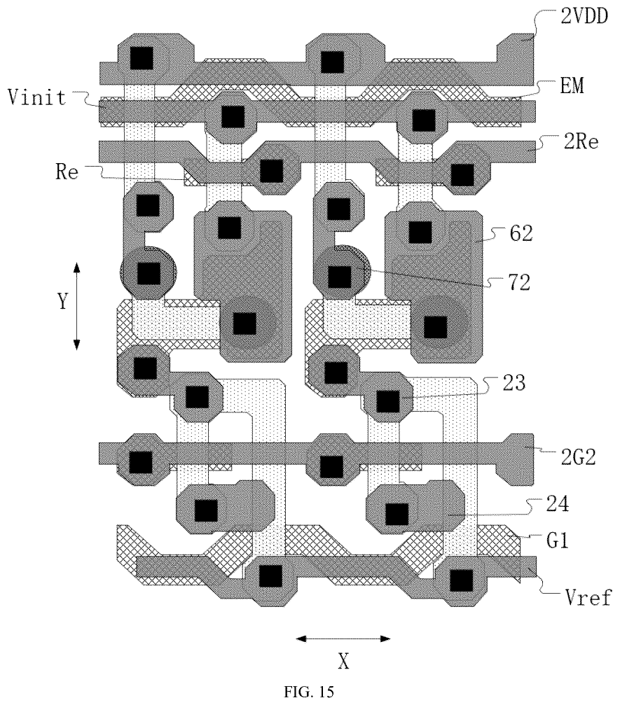

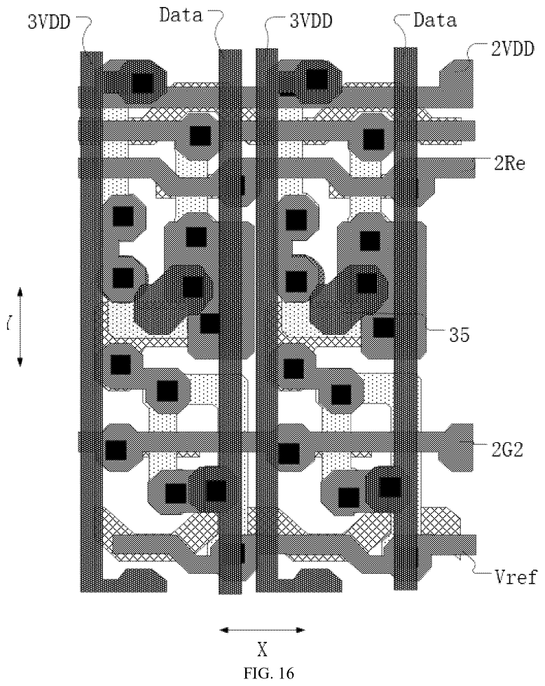

In this exemplary embodiment, the display panel may include a gate layer, an active layer, a Schottky contact layer, a first source-drain layer, a second source-drain layer, and an electrode layer, which are sequentially stacked. Insulating layers are provided between the aforementioned layers. As shown in FIGS. 7-16, FIG. 7 is a structural layout of an exemplary embodiment of the display panel according to this disclosure. FIG. 8 is a structural layout of the gate layer in the display panel shown in FIG. 7. FIG. 9 is a structural layout of the active layer in the display panel shown in FIG. 7. FIG. 10 is a structural layout of the Schottky contact layer in the display panel shown in FIG. 7. FIG. 11 is a structural layout of the first source-drain layer in the display panel shown in FIG. 7. FIG. 12 is a structural layout of the second source-drain layer in the display panel shown in FIG. 7. FIG. 13 is a structural layout of the gate layer and the active layer in the display panel shown in FIG. 7. FIG. 14 is a structural layout of the gate layer, the active layer, and the Schottky contact layer in the display panel shown in FIG. 7. FIG. 15 is a structural layout of the gate layer, the active layer, the Schottky contact layer, and the first source-drain layer in the display panel shown in FIG. 7. FIG. 16 is a structural layout of the gate layer, the active layer, the Schottky contact layer, the first source-drain layer, and the second source-drain layer in the display panel shown in FIG. 7. The display panel includes a plurality of pixel drive circuits arranged in an array along the first direction X and the second direction Y.

As shown in FIGS. 7, 8, and 13, the gate layer may include a gate portion 11, a first gate line G1, a reset signal line Re, a first gate line Ga1, a second gate line G2, and an enable signal line EM. Orthographic projections of the reset signal line Re, the first gate line G1, the second gate line G2, and the enable signal line EM on the base substrate extend in the first direction X. The gate portion 11 is configured to form the gate of the drive transistor T1. A part of the structure of the first gate line G1 is configured to form a gate of the third transistor T3. A part of the structure of the second gate line G2 is configured to form a gate of the second transistor T2. A part of the structure of the reset signal line Re is configured to form a gate of the fourth transistor. A part of the structure of the enable signal line EM is configured to form a gate of the fifth transistor. The second gate line G2 may include a plurality of second gate sub-lines G21 extending in the first direction X and spaced apart. The reset signal line Re may include a plurality of sub-reset signal lines Re1 extending in the first direction X and spaced apart.

As shown in FIGS. 7, 9, and 13, the active layer may include a first active portion 51, a second active portion 52, a third active portion 53, a fourth active portion 54, and a fifth active portion 55. The first active portion 51 includes a first active sub-portion 511 and a second active sub-portion 512 and a third active sub-portion 513 connected to two ends of the first active sub-portion 511. The first active sub-portion 511 is configured to form the channel region of the drive transistor T1. The second active portion 52 is configured to form a channel region of the second transistor T2. The third active portion 53 is configured to form a channel region of the third transistor T3. The fourth active portion 54 is configured to form a channel region of the fourth transistor T4. The fifth active portion 55 is configured to form a channel region of the fifth transistor T5. Additionally, the active layer may further include a sixth active portion 56, a seventh active portion 57, an eighth active portion 58, a ninth active portion 59, a tenth active portion 510, a fourteenth active portion 514, and a fifteenth active portion 515.

As shown in FIGS. 7, 10, and 14, the Schottky contact layer includes a first source portion 61 and a first drain portion 71. The first source portion 61 may be connected to the second active sub-portion 512 through a via hole, and the first source portion 61 may conformally cover the bottom wall and the sidewalls of the via hole. The first drain portion 71 may be connected to the third active sub-portion 513 through a via hole, and the first drain portion 71 may conformally cover the bottom wall and the sidewalls of the via hole.

As shown in FIGS. 7, 11, and 15, the first source-drain layer includes a power line 2VDD, an initial signal line Vinit, a reset connection line 2Re, a second source portion 62, a second drain portion 72, a third bridge portion 23, a fourth bridge portion 24, a second gate connection line 2G2, and a reference voltage line Vref. Orthographic projections of the power line 2VDD, the initial signal line Vinit, the reset connection line 2Re, the reference voltage line Vref, and the second gate connection line 2 G2 on the base substrate extend in the first direction X. The power line 2VDD is connected to an eighth active portion 58 through a via hole to connect to a first pole of the fifth transistor T5. The initial signal line Vinit is connected to a tenth active portion 510 through a via hole to connect to a first pole of the fourth transistor T4. The reference voltage line Vref is connected to the fourteenth active portion 514 through a via hole to connect to a first pole of the third transistor T3. The reset connection line 2Re is connected to a plurality of sub-reset signal lines Rel in the same reset signal line Re through via holes. The second gate connection line 2 G2 is connected to a plurality of second gate sub-lines G21 in the same second gate line G2 through via holes. In this exemplary embodiment, a sheet resistance of the first source-drain layer is smaller than that of the gate layer. This configuration may reduce the voltage difference between the gates of the fourth transistors T4 connected to the same reset signal line Re, as well as the voltage difference between the gates of the second transistors connected to the same second gate line G2, thereby improving the display uniformity of the display panel. It should be understood that in other exemplary embodiments, other gate lines may also include gate sub-lines distributed and extending in the first direction. Correspondingly, the first source-drain layer may include connection lines. Orthographic projections of the connection lines on the base substrate extend in the first direction. The connection lines are connected to a plurality of gate sub-lines in the same gate line through via holes. Here, the gate lines are signal lines extending in the first direction and configured to form the gates of transistors, such as the first gate line and the enable signal line being the gate line. The second source portion 62 covers the first source portion 61, and a part of the second source portion 62 is located within the via hole of the first source portion 61. The second drain portion 72 covers the first drain portion 71, and a part of the second drain portion 72 is located in the via hole of the first drain portion 71. The third bridge portion 23 is connected to a sixth active portion 56 and the gate portion 11 through via holes to connect the second pole of the second transistor T2 and the gate of the drive transistor T1. The fourth bridge portion 24 is connected to the seventh active portion 57 through a via hole to connect the first pole of the second transistor T2.

As shown in FIGS. 7, 8, and 11, a length direction of the channel region of the drive transistor is the first direction X. The gate portion 11 includes a first gate portion 111, and the second source portion 62 includes a first conductive portion 621. An orthographic projection of the first gate portion 111 on the base substrate is located on a side of the orthographic projection of the first active sub-portion 511 on the base substrate in the second direction Y. An orthographic projection of the second source portion 62 on the base substrate is located on a side of the orthographic projection of the first active sub-portion 511 on the base substrate in the second direction Y. The orthographic projection of the first gate portion 111 on the base substrate and the orthographic projection of the first conductive portion 621 on the base substrate at least partially overlap. The first gate portion 111 may be configured to form the first electrode of the capacitor, and the first conductive portion 621 may be configured to form the second electrode of the capacitor.

As shown in FIGS. 7, 12, and 16, the second source-drain layer includes: a data line Data, a power connection line 3VDD, and a fifth bridge portion 35. The data line Data is connected to the fourth bridge portion 24 through a via hole to connect to the first pole of the second transistor. The power connection line 3VDD is connected to the power line 2VDD, which intersects with the power connection line, through a via hole. The power connection line 3VDD and the power line 2VDD form a grid structure. The power line with the grid structure has a lower resistance, thereby improving the display uniformity of the display panel. The fifth bridge portion 35 may be connected to the second source portion 62 through a via hole.

As shown in FIG. 7, the electrode layer may include a plurality of electrode portions, which may include an electrode portion R, an electrode portion G (not shown), and an electrode portion B. The electrode portion may be connected to the fifth bridge portion 35 through a via hole to connect to the source of the drive transistor.

It should be noted that as shown in FIGS. 7, 14, 15, and 16, black squares drawn on a side of the Schottky contact layer away from the base substrate represent via holes connecting the Schottky contact layer to other layers on a side facing the base substrate. The black squares drawn on the side of the first source-drain layer away from the base substrate represent via holes connecting the first source-drain layer to other layers facing a side of the base substrate. Black squares drawn on a side of the second source-drain layer away from the base substrate represent via holes connecting the second source-drain layer to other layers facing the side of the base substrate. Black squares drawn on a side of the electrode layer away from the base substrate represent via holes connecting the electrode layer to other layers facing the side of the base substrate. The different via holes represented by black squares at different positions may penetrate through different insulating layers.

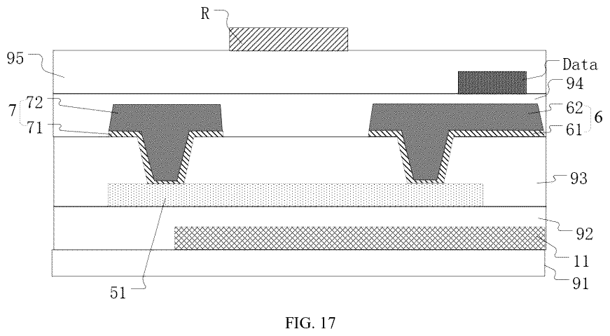

As shown in FIG. 17, it is a partial sectional view of the display panel shown in FIG. 7 taken along a dashed line AA. The display panel includes a base substrate 91, a gate layer, a first insulating layer 92, an active layer, a dielectric layer 93, a Schottky contact layer, a first source-drain layer, a passivation layer 94, a planarization layer 95, and an electrode layer sequentially stacked. The first insulating layer 92 may be a single-layer or multi-layer structure and may include at least one of silicon nitride, silicon oxide, or silicon oxynitride. The dielectric layer 93 may be made of an organic material, such as polyimide (PI), polyethylene terephthalate (PET), polyethylene naphthalate (PEN), or silicon-on-glass (SOG) structures. The passivation layer 94 may be a silicon oxide layer. The base substrate 91 may include a glass substrate, a barrier layer, and a polyimide layer sequentially stacked. The barrier layer may be an inorganic material. The material of the gate layer may be molybdenum, aluminum, copper, titanium, niobium, or alloys thereof, or conductive layers such as molybdenum/titanium alloy or laminated layers. The first source-drain layer and the second source-drain layer may include metal materials, such as molybdenum, aluminum, copper, titanium, niobium, or alloys thereof, or conductive layers such as molybdenum/titanium alloy or laminated layers, or titanium/aluminum/titanium laminated layers.

It should be noted that proportions in the drawings of this disclosure may serve as references for actual processes but not limited thereto. For example, the width-to-length ratio of the channel, the thickness and spacing of each film layer, and the width and spacing of each signal line may be adjusted according to actual needs. The number of pixels in the display substrate and the number of sub-pixels in each pixel are not limited to the numbers shown in the drawings. The drawings described in this disclosure are only schematic structural views. Additionally, terms such as “first” and “second” are only used to distinguish different structural names and do not imply a specific order. Structures in the same layer may be formed through the same patterning process. In this exemplary embodiment, an orthographic projection of a certain structure on the base substrate extending in a certain direction may be understood as an orthographic projection of the structure on the base substrate extending linearly or bending in the direction.

This exemplary embodiment also provides a display device, which includes the display panel above mentioned. The display device may be mobile phones, tablet computers, televisions, or other display device.

Other embodiments of this disclosure will be apparent to those skilled in the art from consideration of the specification and practice of the invention disclosed here. This application is intended to cover any variations, uses, or adaptations of this disclosure following the general principles thereof and including common knowledge or conventional technical means in the art that is not disclosed herein. The specification and embodiments are considered to be merely exemplary, and the true scope and spirit of this disclosure is indicated by the appended claims.

It should be understood that this disclosure is not limited to the precise structures that have been described above and illustrated in the accompanying drawings, and various modifications and changes may be made without departing from the scope thereof. The scope of this disclosure is merely limited by the appended claims.

1. A display panel, comprising a pixel drive circuit, the pixel drive circuit comprising a drive transistor, and the drive transistor outputting a drive current based on a gate-source voltage difference thereof, wherein the display panel further comprises:
a base substrate;
a first active portion comprising a first active sub-portion and a second active sub-portion connected to each other, the first active sub-portion being configured to form a channel region of the drive transistor, and the second active sub-portion being of a semiconductor structure;
a source portion having a conductor structure, the source portion and the second active sub-portion forming a Schottky contact, and the source portion being configured to form a source of the drive transistor; and
a gate portion, an orthographic projection of the gate portion on the base substrate covering an orthographic projection of the first active sub-portion on the base substrate, and the gate portion being configured to form a gate of the drive transistor,
wherein in a stacking direction of the base substrate and the first active portion, at least a part of the source portion and at least a part of the gate portion are respectively located on two sides of the second active sub-portion, and orthographic projections of the source portion and the gate portion located on the two sides of the second active sub-portion on the base substrate at least partially overlap.

2. The display panel according to claim 1, wherein a conduction band minimum of the second active sub-portion is less than a work function of a contact portion of the source portion with the second active sub-portion.

3. The display panel according to claim 2, wherein a difference between the work function of the contact portion of the source portion with the second active sub-portion and the conduction band minimum of the second active sub-portion is greater than or equal to 0.3 eV.

4. The display panel according to claim 1, wherein orthographic projections of the source portion and the gate portion located on the two sides of the second active sub-portion on the base substrate and an orthographic projection of the second active sub-portion on the base substrate have a common overlapping region.

5. The display panel according to claim 1, wherein the source portion comprises a first source portion and a second source portion;
the first source portion is connected to the second active sub-portion through a via hole, and the first source portion conformally covers at least a part of a sidewall and at least a part of a bottom wall of the via hole;
the second source portion is located on a side of the first source portion away from the second active sub-portion, and the second source portion at least partially fills the via hole.

6. The display panel according to claim 5, wherein the first source portion comprises one or more of silver oxide, platinum, titanium oxide, and molybdenum oxide.

7. The display panel according to claim 1, wherein the source portion is located on a side of the first active portion away from the base substrate, and the gate portion is located between the first active portion and the base substrate.

8. The display panel according to claim 1, wherein the gate portion is located on a side of the first active portion away from the base substrate;
the source portion comprises a third source portion and a fourth source portion, the third source portion forms a Schottky contact with the second active sub-portion, the third source portion is at least partially located between the second active sub-portion and the base substrate, and the fourth source portion is connected to the third source portion through a via hole;
an orthographic projection of the third source portion on the base substrate at least partially overlap with the orthographic projection of the gate portion on the base substrate.

9. The display panel according to claim 1, wherein the drive transistor is an N-type transistor, a source of the drive transistor is an output terminal of the drive current, and the pixel drive circuit further comprises a capacitor, a first electrode of the capacitor being connected to the gate of the drive transistor, and a second electrode of the capacitor being connected to the source of the drive transistor;
at least a part of the gate portion is reused as the first electrode of the capacitor, and at least a part of the source portion is reused as the second electrode of the capacitor.

10. The display panel according to claim 5, wherein the first active portion further comprises a third active sub-portion, and the first active sub-portion is connected between the second active sub-portion and the third active sub-portion;
the display panel further comprises:
a drain portion having a conductor structure, the drain portion forming a Schottky contact with the third active sub-portion, and the drain portion being configured to form a drain of the drive transistor.

11. The display panel according to claim 1, wherein a width-to-length ratio of the channel region of the drive transistor is 2/2 to 2/10.

12. The display panel according to claim 1, wherein the display panel further comprises:
a gate layer on a side of the base substrate, the gate layer comprising the gate portion;
an active layer on a side of the gate layer away from the base substrate, the active layer comprising the first active portion;
a Schottky contact layer comprising a first source portion, the first source portion and the second active sub-portion forming a Schottky contact; and
a first source-drain layer on a side of the Schottky contact layer away from the base substrate, the first source-drain layer comprising a second source portion, and the second source portion being electrically connected to the first source portion,
wherein the first source portion and the second source portion constitute the source portion.

13. The display panel according to claim 12, wherein the display panel further comprises:
a dielectric layer between the active layer and the Schottky contact layer, the dielectric layer being provided with a via hole, and the via hole exposing at least a part of the second active sub-portion out of the dielectric layer,
wherein the first source portion conformally covers at least a part of a sidewall and at least a part of a bottom wall of the via hole, and the second source portion at least partially fills the via hole.

14. The display panel according to claim 12, wherein the first active portion further comprises a third active sub-portion, and the first active sub-portion is connected between the second active sub-portion and the third active sub-portion;
the Schottky contact layer comprises a first drain portion, and the first drain portion and the third active sub-portion form a Schottky contact;
the first source-drain layer further comprises a second drain portion, the second drain portion is electrically connected to the first drain portion, and the first drain portion and the second drain portion constitute a drain of the drive transistor.

15. The display panel according to claim 12, wherein a length direction of the channel region of the drive transistor is a first direction;
the gate portion comprises a first gate portion; the second source portion comprises a first conductive portion; an orthographic projection of the first gate portion on the base substrate is located on a side, in a second direction, of an orthographic projection of the first active sub-portion on the base substrate; and an orthographic projection of the second source portion on the base substrate is located on a side, in the second direction, of the orthographic projection of the first active sub-portion on the base substrate;
the orthographic projection of the first gate portion on the base substrate at least partially overlaps with an orthographic projection of the first conductive portion on the base substrate, and the first direction intersects with the second direction.

16. The display panel according to claim 15, wherein the pixel drive circuit further comprises a fourth transistor, and the fourth transistor has a first pole connected to an initial signal line, a second pole connected to the source of the drive transistor, and a gate connected to a reset signal line;
the gate layer further comprises the reset signal line, and an orthographic projection of the reset signal line on the base substrate extends in the first direction;
in the second direction, the orthographic projection of the first gate portion on the base substrate and the orthographic projection of the second source portion on the base substrate are located between the orthographic projection of the reset signal line on the base substrate and the orthographic projection of the first active sub-portion on the base substrate.

17. The display panel according to claim 12, wherein the pixel drive circuit further comprises a switching transistor;
the gate layer further comprises a gate line, an orthographic projection of the gate line on the base substrate extends in a first direction, and a part of the gate line is configured to form a gate of the switching transistor;
wherein the gate line comprises gate sub-lines spaced apart and extending in the first direction, the first source-drain layer further comprises a connection line, an orthographic projection of the connection line on the base substrate extends in the first direction, and the connection line connects a plurality of gate sub-lines in a same gate line through via holes;
a sheet resistance of the gate layer is greater than a sheet resistance of the first source-drain layer.

18. The display panel according to claim 12, wherein the pixel drive circuit further comprises:
a second transistor having a first pole connected to a data line, a second pole connected to the gate of the drive transistor, and a gate connected to a second gate line;
a third transistor having a first pole connected to a reference voltage line, a second pole connected to the gate of the drive transistor, and a gate connected to a first gate line;
a fourth transistor having a first pole connected to an initial signal line, a second pole connected to the source of the drive transistor, and a gate connected to a reset signal line; and
a fifth transistor having a first pole connected to a power line, a second pole connected to a drain of the drive transistor, and a gate connected to an enable signal line,
wherein the first gate line, the second gate line, the reset signal line, and the enable signal line are located in the gate layer, a part of the first gate line is configured to form a gate of the third transistor; a part of the second gate line is configured to form a gate of the second transistor; a part of the reset signal line is configured to form a gate of the fourth transistor, and a part of the enable signal line is configured to form a gate of the fifth transistor;
orthographic projections of the first gate line, the second gate line, the reset signal line, and the enable signal line on the base substrate extend in a first direction;
in a same pixel drive circuit, an orthographic projection of the enable signal line on the base substrate, an orthographic projection of the reset signal line on the base substrate, an orthographic projection of the gate portion on the base substrate, an orthographic projection of the second gate line on the base substrate, and an orthographic projection of the first gate line on the base substrate are sequentially distributed in a second direction, and the first direction intersects with the second direction.

19. A display device, comprising a display panel, the display panel comprising a pixel drive circuit, the pixel drive circuit comprising a drive transistor, and the drive transistor outputting a drive current based on a gate-source voltage difference thereof, wherein the display panel further comprises:
a base substrate:
a first active portion comprising a first active sub-portion and a second active sub-portion connected to each other, the first active sub-portion being configured to form a channel region of the drive transistor, and the second active sub-portion being of a semiconductor structure;
a source portion having a conductor structure, the source portion and the second active sub-portion forming a Schottky contact, and the source portion being configured to form a source of the drive transistor; and
a gate portion, an orthographic projection of the gate portion on the base substrate covering an orthographic projection of the first active sub-portion on the base substrate, and the gate portion being configured to form a gate of the drive transistor.
wherein in a stacking direction of the base substrate and the first active portion, at least a part of the source portion and at least a part of the gate portion are respectively located on two sides of the second active sub-portion, and orthographic projections of the source portion and the gate portion located on the two sides of the second active sub-portion on the base substrate at least partially overlap.

20. The display device according to claim 19, wherein a conduction band minimum of the second active sub-portion is less than a work function of a contact portion of the source portion with the second active sub-portion.
